(19) United States
(12) Patent Application Publication
(10) Pub. No.: US 2024/0071469 A1
(43) Pub. Date: Feb. 29, 2024

(54) MEMORY WITH SINGLE TRANSISTOR SUB-WORD LINE DRIVERS, AND ASSOCIATED SYSTEMS, DEVICES, AND METHODS

(71) Applicant: Micron Technology, Inc., Boise, ID (US)

(72) Inventor: Tae H. Kim, Boise, ID (US)

(21) Appl. No.: 17/894,089

(22) Filed: Aug. 23, 2022

(51) Int. Cl. G11C 11/408; G11C 11/4074; G11C 11/4093

(52) U.S. Cl. CPC G11C 11/4085; G11C 11/4074; G11C 11/4093

(57) ABSTRACT

Memory with single transistor sub-word line drivers, and associated systems, devices, and methods are disclosed herein. In one embodiment, an apparatus comprises a plurality of first sub-word line drivers and a plurality of second sub-word line drivers. Each sub-word line driver of the plurality of first sub-word line drivers is coupled to (a) a first global word line and (b) a corresponding one of a plurality of first local word lines. Each sub-word line driver of the plurality of second sub-word line drivers is coupled to (a) a second global word line different from the first global word line and (b) a corresponding one of a plurality of second local word lines. In addition, individual ones of the plurality of first local word lines are interleaved with individual ones of the plurality of second local word lines.

### TECHNICAL FIELD

The present disclosure is related to memory systems, devices, and associated methods. For example, several embodiments of the present disclosure are directed to memory systems and devices with sub-word line drivers that each include a single transistor.

### BACKGROUND

Memory devices are widely used to store information related to various electronic devices such as computers, wireless communication devices, cameras, digital displays, and the like. Memory devices are frequently provided as internal, integrated circuits and/or as part of external removable devices in computers or other electronic devices. There are many different types of memory, including volatile and non-volatile memory. Volatile memory, including static random-access memory (SRAM), dynamic random-access memory (DRAM), and synchronous dynamic random-access memory (SDRAM), among others, may require a source of applied power to maintain its data. Non-volatile memory, by contrast, can retain its stored data even when not externally powered. Non-volatile memory is available in a wide variety of technologies, including flash memory (e.g., NAND and NOR) phase change memory (PCM), ferroelectric random-access memory (FeRAM), resistive random-access memory (RRAM), and magnetic random-access memory (MRAM), among others. Improving memory devices, generally, may include increasing memory cell density, increasing performance (e.g., read, write, erase speeds) or otherwise reducing operational latency, increasing reliability, increasing data retention, reducing power consumption, reducing manufacturing costs, or reducing dimensional attributes, among other metrics.

### BRIEF DESCRIPTION OF THE DRAWINGS

The present disclosure will be understood more fully from the detailed description given below and from the accompanying drawings of various embodiments of the present disclosure. The components in the drawings are not necessarily to scale. Instead, emphasis is placed on illustrating clearly the principles of the present technology. The drawings should not be taken to limit the disclosure to the specific embodiments depicted, but are for explanation and understanding only.

FIG. 1A is a block diagram schematically illustrating a memory system configured in accordance with various embodiments of the present technology.

FIG. 1B is a block diagram schematically illustrating a memory device configured in accordance with various embodiments of the present technology.

FIG. 2 is a diagram schematically illustrating a plurality of sub-word line drivers corresponding to word lines of a memory cell matrix, the sub-word line drivers configured in accordance with various embodiments of the present technology.

FIG. 3A is a signal diagram illustrating a method of operating sub-word line drivers in accordance with various embodiments of the present technology.

FIG. 3B is a diagram schematically illustrating the embodiment of FIG. 2 during a state of operation corresponding to the method illustrated in FIG. 3A.

FIG. 4 is a block diagram of a system having a memory device configured in accordance with various embodiments of the present technology.

### DETAILED DESCRIPTION

As discussed in greater detail below, the technology disclosed herein relates to memory systems and devices having sub-word line drivers that each include a single (e.g., only one) transistor. The transistor can be coupled to (a) a main word line driven by a main word line driver of a memory device and (b) to a local word line corresponding to a memory cell matrix. The transistor can further be coupled to a phase driver configured to selectively activate the transistor to selectively couple the local word line to the main word line via the transistor.

In some embodiments, the local word line can be included in a first set of local word lines that are each coupled to the main word line via a transistor of a corresponding sub-word line driver. A second set of local word lines that correspond to the memory cell matrix can be (a) coupled to a different main word line and (b) interleaved with the local word lines of the first set. When one of the local word lines of the first set is selected and fired (e.g., for memory operations), the other local word lines of the first set can be floated, and local word lines of the second set can be used to shield the floating, unselected local word lines of the first set from the selected and fired local word line of the first set.

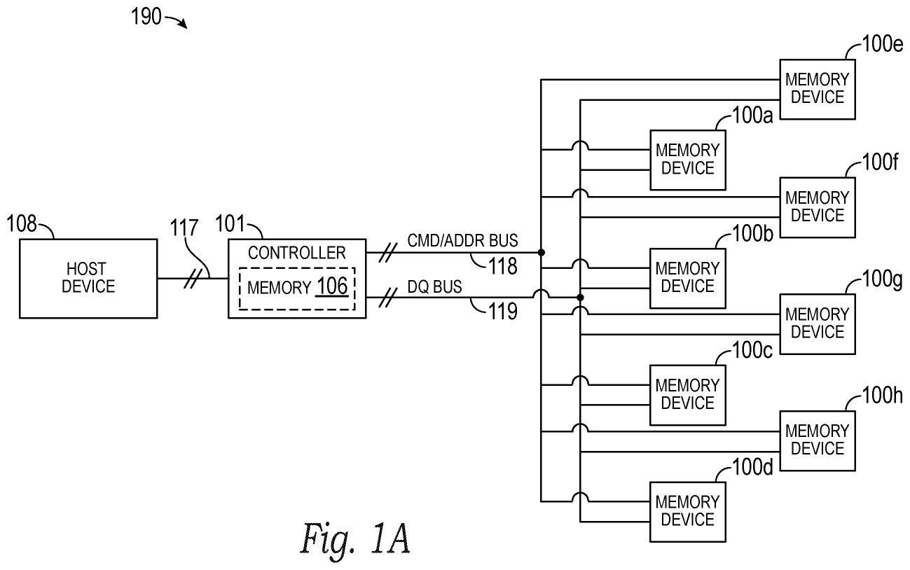

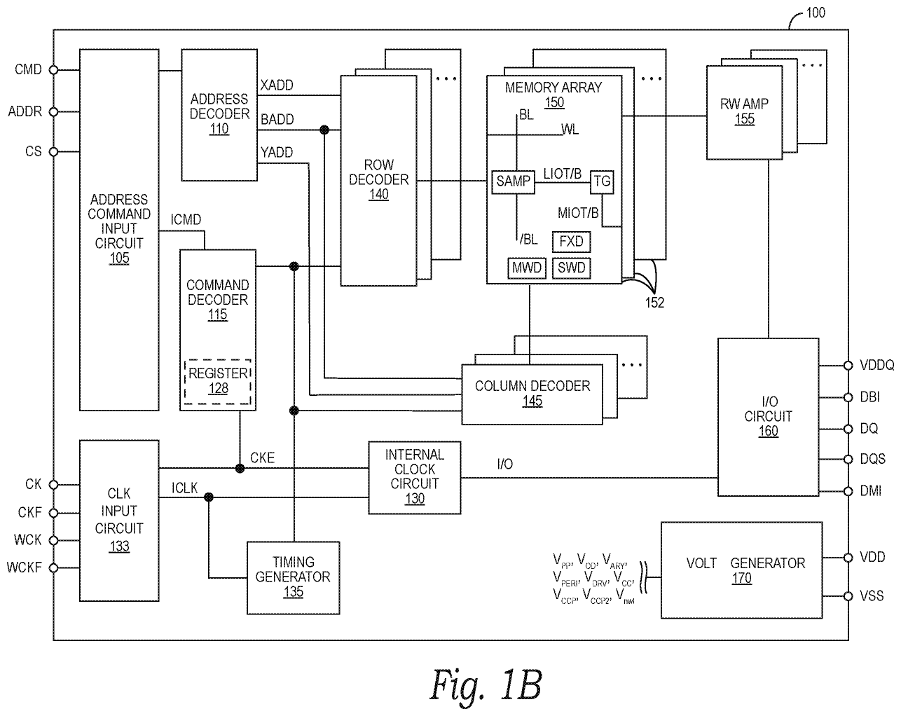

In the illustrated embodiments below, the memory devices and systems are primarily described in the context of devices incorporating DRAM storage media. Memory devices configured in accordance with other embodiments of the present technology, however, can include other types of memory devices and systems incorporating other types of storage media, including PCM, SRAM, FRAM, RRAM, MRAM, read only memory (ROM), erasable programmable ROM (EPROM), electrically erasable programmable ROM (EEROM), ferroelectric, magnetoresistive, and other storage media, including non-volatile (e.g., flash, NAND and/or NOR) storage media. A person skilled in the art will understand that the technology may have additional embodiments and that the technology may be practiced without several of the details of the embodiments described below with reference to FIGS. 1-4.

### A. Overview

Sub-word line drivers are often used in combination with main word line drivers to drive voltages onto local word lines for memory operations. For example, a sub-word line driver can be coupled to a global word line that is driven by a main word line driver. When a local word line corresponding to the sub-word line driver is selected for memory operations, a first transistor of the sub-word line driver can be activated to couple the local word line to the global word line and ramp a voltage on the local word line to a high voltage driven onto the global word line by the main word line driver. Activation of the first transistor can be controlled by a first phase driver. When an adjacent local word line (e.g., a local word line of a same memory cell matrix) is selected, a second transistor of the sub-word line driver can be activated to couple the local word line to a low voltage line to drop the voltage on the local word line. Activation of the second transistor can be controlled by a second phase driver. In other words, the sub-word line driver can be used to ramp the corresponding local word line to a high voltage when the local word line is selected for memory operations, and to drop the local word line to a low voltage when adjacent local word lines are selected for memory operations. Thus, the first transistor of the sub-word line driver can be considered a pull-up transistor, and the second transistor of the sub-word line driver can be considered a pull-down transistor.

The multiple transistor arrangement of the sub-word line driver takes up a relatively large amount of space, especially as the sub-word line driver is replicated for every word line across a memory array. In addition, the multiple transistor arrangement of the sub-word line driver requires multiple phase drivers to selectively activate the transistors. Using multiple phase drivers per sub-word line driver can take up a relatively large amount space and consume a relatively large amount of power.

To address these concerns, the present technology is directed to memory devices and systems employing sub-word line drivers that include a single (e.g., only one) transistor. In some embodiments, the transistor of a sub-word line driver is an nMOS transistor, a pMOS transistor, or another type of transistor. The transistor is selectively activated using a phase driver. Therefore, only one phase driver is used to control a sub-word line driver in some embodiments. Thus, in comparison to the sub-word line drivers discussed above, sub-word line drivers of the present technology can have a relatively smaller footprint (e.g., through use of a single transistor and/or a single phase driver per sub-word line driver) and can consume less power (e.g., through use of a single phase driver per sub-word line driver).

Furthermore, word lines of a memory cell matrix can be electrically coupled to one of two global word lines. For example, a first set of word lines can be coupled to a first global word line, and a second set of word lines can be coupled to a second global word line. Word lines of the first set can be interleaved with word lines of the second set in the memory cell mat. Using two global word lines instead of one global word line allows at least some unselected word lines of a memory cell matrix to be floated. More specifically, when a word line of one of the sets is selected and fired, the other word lines of that set can be floated, and word lines of the other set can be dropped to a low voltage to shield the floating word lines from coupling noise with the fired word line. Floating at least some of the unselected word lines rather than dropping all of the unselected word lines to a low voltage is expected to reduce the power consumed by a memory device incorporating the sub-word line drivers of the present technology.

Moreover, the word lines of a memory cell matrix of the present technology can terminate at the memory cell matrix. Stated another way, word lines of a memory cell matrix may not pass through to the global memory array. Such an arrangement is often easier and less costly to manufacture than arrangements with pass through word line configurations.

B. Selected Embodiments of Memory with Single MOS Sub-Word Line Drivers, and Associated Systems, Devices, and Methods

FIG. 1A is a block diagram schematically illustrating a memory system 190 (e.g., a dual in-line memory module (DIMM)) configured in accordance with various embodiments of the present technology. In the illustrated embodiment, the memory system 190 includes a plurality of memory devices 100 (identified individually as memory devices 100a-100h), a controller 101, and a host device 108. In some embodiments, the memory devices 100 can be DRAM memory devices. Although illustrated with eight memory devices 100 in FIG. 1A, the memory system 190 can include a greater or lesser number of memory devices 100 in other embodiments of the present technology. Well-known components of the memory system 190 have been omitted from FIG. 1A and are not described in detail below so as to avoid unnecessarily obscuring aspects of the present technology.

The memory devices 100 can be connected to one or more electronic devices that are capable of utilizing memory for temporary or persistent storage of information, or a component thereof. For example, one or more of the memory devices 100 can be operably connected to one or more host devices. As a specific example, the memory devices 100 of the memory system 190 are connected to a host device 101 (hereinafter referred to as a “memory controller 101”) and to a host device 108.

The memory devices 100 of FIG. 1A are operably connected to the memory controller 101 via a command/address (CMD/ADDR) bus 118 and a data (DQ) bus 119. As described in greater detail below with respect to FIG. 1B, the CMD/ADDR bus 118 and the DQ bus 119 can be used by the memory controller 101 to communicate commands, memory addresses, and/or data to the memory devices 100. In response, the memory devices 100 can execute commands received from the memory controller 101. For example, in the event a write command is received from the memory controller 101 over the CMD/ADDR bus 118, the memory devices 100 can receive data from the memory controller 101 over the data DQ bus 119 and can write the data to memory cells corresponding to memory addresses received from the memory controller 101 over the CMD/ADDR bus 118. As another example, in the event a read command is received from the memory controller 101 over the CMD/ADDR bus 118, the memory devices 100 can output data to the memory controller 101 over the data DQ bus 119 from memory cells corresponding to memory addresses received from the memory controller 101 over the CMD/ADDR bus 118.

In the illustrated example, the memory controller 101 includes a memory 106 configured to store various processes, logic flows, and routines for controlling operation of the memory system 190, including managing the memory devices 100 and handling communications between the memory devices 100 and the host device 108. In some embodiments, the memory 106 can include memory registers storing, for example, memory pointers, fetched data, etc. The memory 106 can also include read-only memory (ROM) or other non-volatile memory, and/or volatile memory (e.g., SRAM). Although shown embedded in the memory controller 101 in FIG. 1A, the memory 106 can be positioned at other locations in the memory system 190 in other embodiments of the present technology, such as exterior the memory controller 101, the host device 108, and/or one or more of the memory devices 100a-100h.

The host device 108 of FIG. 1A may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device 108 may be a networking device (e.g., a switch, a router, etc.); a recorder of digital images, audio, and/or video; a vehicle; an appliance; a toy; or any one of a number of other products. In one embodiment, the host device 108 may be connected directly to one or more of the memory devices 100 (e.g., via a communications bus of signal traces (not shown)). Additionally, or alternatively, the host device 108 may be indirectly connected to one or more of the memory devices 100 (e.g., over a networked connection or through intermediary devices, such as through the memory controller 101 and/or via a communications bus 117 of signal traces).

FIG. 1B is a block diagram schematically illustrating a memory device 100 configured in accordance with various embodiments of the present technology. The memory device 100 may include an array of memory cells, such as memory array 150. The memory array 150 may include a plurality of memory banks 152 (e.g., four banks, eight banks, sixteen banks, thirty-two banks, or any other number of memory banks), and each memory bank 152 may include a plurality of word lines (WL), a plurality of bit lines (BL), and a plurality of memory cells (e.g., m×n memory cells) arranged at intersections of the word lines (e.g., m word lines, which may also be referred to as memory rows) and the bit lines (e.g., n bit lines, which may also be referred to as memory columns). The memory array 150 (e.g., each memory bank 152) can be divided into smaller sections or subarrays, and the subarrays can be split into memory cell matrices (MATs). Memory cells of the memory array 150 can include any one of a number of different memory media types, including capacitive, phase change, magnetoresistive, ferroelectric, or the like.

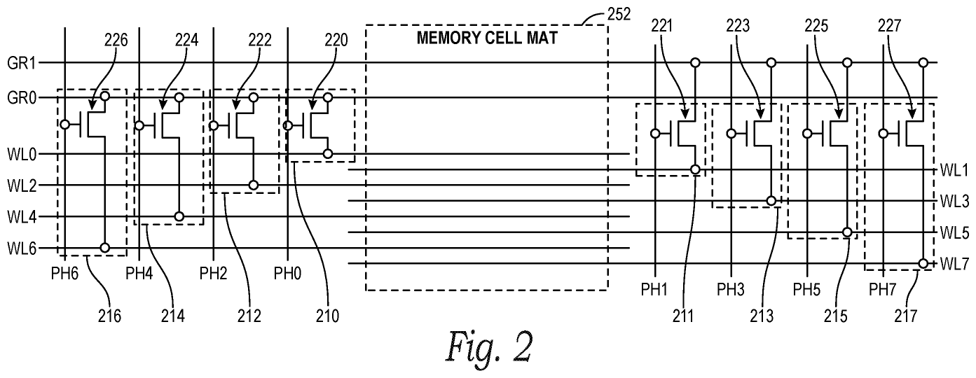

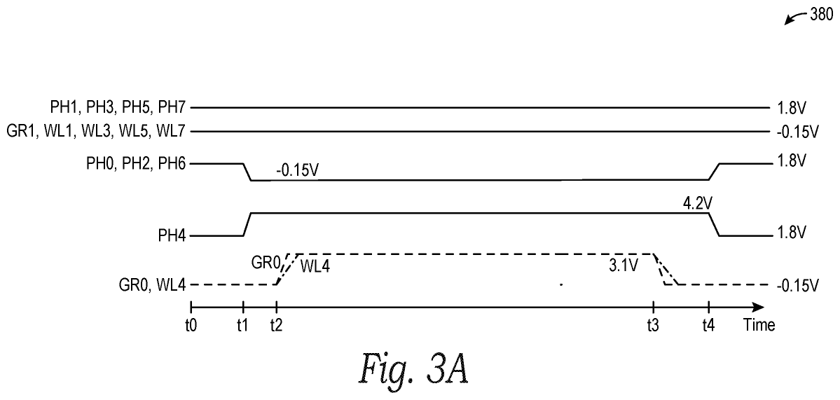

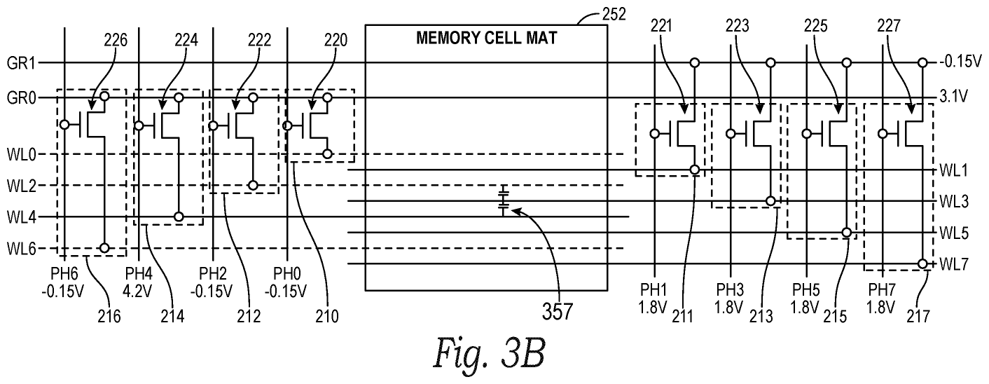

The memory array 150 further includes global word line drivers (referred to herein as main word line drivers (MWDs)), local word line drivers (referred to herein as sub-word line drivers (SWDs)), and phase drivers (FXDs). The MWDs, SWDs, and FXDs are coupled to corresponding word lines WL, and are configured to control voltage levels on the corresponding word lines WL during memory operations. For example, each word line WL can be coupled to one or more global rows or global word lines (GR) that are each driven by a corresponding MWD. More specifically, each global word line GR driven by a MWD can be coupled to eight SWDs, sixteen SWDs, or some other desired number of SWDs, and each the SWD can be coupled to corresponding word lines WL (e.g., local word lines) of one or more of the subarrays and/or one or more of the memory cell MATs of the memory array 150. The SWDs can be used in combination with the MWDs to control voltage levels on the corresponding word lines WL. The FXDs provide phase signals PH to the SWDs to select SWDs for memory operations based on decoded row address signals and timing control signals. The MWDs, SWDs, and FXDs are discussed in greater detail below with reference to FIGS. 2-3B.

The selection of a word line WL for memory operations may be performed by a row decoder 140, and the selection of a bit line BL (and/or a bit line/BL) for memory operations may be performed by a column decoder 145. In the illustrated embodiment, the row decoder 140 includes a respective row decoder for each memory bank 152, and the column decoder 145 includes a respective column decoder for each memory bank 152.

Sense amplifiers (SAMP) may be provided for corresponding bit lines BL and/BL, and can be connected to at least one respective local I/O line pair (LIOT/B) that, in turn, can be coupled to at least one respective main I/O line pair (MIOT/B) via transfer gates (TG) that can function as switches. Read data from the bit line BL or the bit line/BL is amplified by the sense amplifier SAMP, and transferred to read/write amplifiers 155 over the local I/O line pair, the transfer gates TG, and the main I/O line pair MIOT/B. Write data output from the read/write amplifiers 155 is transferred to the sense amplifier SAMP over the main I/O line pair MIOT/B, the transfer gates TG, and the local I/O line pair LIOT/B, and thereafter written in or stored to a memory cell coupled to the bit line BL or the bit line/BL.

The memory device 100 may employ a plurality of external terminals that include command and address terminals coupled to a command/address bus (e.g., the CMD/ADDR bus 118 of FIG. 1A) to receive command signals CMD and address signals ADDR, respectively. The memory device may further include a chip select terminal to receive a chip select signal CS; clock terminals to receive clock signals CK and/or CKF; data clock terminals to receive data clock signals WCK, WCKF, and/or DQS; data terminals DQ, DBI (for data bus inversion function), and/or DMI (for data mask inversion function); and/or power supply terminals V_{DD}, V_{SS}, V_{DDQ}, and/or V_{SSQ} (not shown).

The power supply terminals may be supplied with power supply potentials V_{DD} and V_{SS}. These power supply potentials V_{DD} and V_{SS} can be supplied to an internal voltage generator circuit 170. The internal voltage generator circuit 170 can generate various internal potentials V_{PP}, V_{OD}, V_{ARY}, V_{PERI}, Vnwl, V_{DRV}, V_{CC}, V_{CCP}, V_{CCP2}, and the like based on the power supply potentials V_{DD} and V_{SS}. In some embodiments, one or more of these internal potentials can be externally supplied to the memory device 100, and/or some of these internal potentials can be generated by other circuits of the memory device 100 (instead of the voltage generator circuit 170) based on, for example, the power supply potentials V_{DD} and V_{SS}.

The internal potential V_{PP} can be used in the row decoder 140, the internal potentials V_{OD} and V_{ARY} can be used in the sense amplifiers included in the memory array 150, and the internal potential V_{PERI} can be used in various circuit blocks of the memory device 100. The negative word line voltage Vnwl, the driver voltage V_{DRV}, the common collector voltage V_{CC}, the common collector pumped voltage V_{CCP}, and/or the common collector pumped voltage V_{CCP2} can be used, for example, in the memory array 150, such as by the MWDs, the SWDs, and/or the FXDs. In some embodiments, the common collector voltage V_{CC} can be in a range from about 2.3 volts to 2.7 volts (e.g., 2.5 volts); the common collector pumped voltage V_{CCP} can be in a range from about 3.0 volts to about 3.5 voltage (e.g., 3.1 volts); and the common collector pumped voltage V_{CCP2} can be in a range from about 4.0 volts to about 4.5 volts (e.g., 4.2 volts). In these and other embodiments, the driver voltage V_{DRV} can be in a range from about 1.5 volts to about 2.0 volts (e.g., 1.8 volts), and the negative word line voltage Vnwl can be in a range from about −0.1 volts to about −0.25 volts (e.g., −0.15 volts).

The power supply terminals may also be supplied with power supply potentials V_{DDQ} and/or V_{SSQ} (not shown). The power supply potentials V_{DDQ} and V_{SSQ} can be supplied to an input/output circuit 160 together with the power supply potentials V_{DD} and V_{SS}. The power supply potentials V_{DDQ} and V_{SSQ} can be the same potentials as the power supply potentials V_{DD} and V_{SS}, respectively, in some embodiments of the present technology. The power supply potentials V_{DDQ} and V_{SSQ} can be different potentials from the power supply potentials V_{DD} and V_{SS}, respectively, in other embodiments of the present technology. The power supply potentials V_{DDQ} and V_{SSQ} can be used for the input/output circuit 160 so that power supply noise generated by the input/output circuit 160 does not propagate to the other circuit blocks of the memory device 100.

The external clock signals CK and CKF received at the clock terminals and/or the external data clock signals WCK and WCKF received at the data clock terminals can be supplied to a clock input circuit 133. For example, when enabled by a clock enable signal CKE, input buffers included in the clock input circuit 133 can receive the clock signals CK and CKF and/or the data clock signals WCK and WCKF. The CK and CKF signals can be complementary, and/or the WCK and WCKF signals can be complementary.

The clock input circuit 133 can generate an internal clock signal ICLK based on the clock signals CK, CKF, WCK, and/or WCKF. The internal clock signal ICLK signal can be supplied to an internal clock circuit 130. In turn, the internal clock circuit 130 can provide various phase and frequency controlled internal clock signals based on the internal clock signals ICLK and/or the clock enable signal CKE. The phase and frequency controlled internal clock signals can be used for timing operation of various internal circuits of the memory device 100. For example, the internal clock circuit 130 can provide input/output clock signals I/O to the input/output circuit 160 of the memory device 100. The input/output clock signals I/O can be used as timing signals for determining an output timing of read data and/or an input timing of write data. The input/output clock signals I/O can be provided at multiple clock frequencies so that data can be output from and/or input into the memory device 100 at different data rates. A higher clock frequency may be desirable when high memory speed is desired. A lower clock frequency may be desirable when lower power consumption is desired. The internal clock signals ICLK can additionally or alternatively be supplied to a timing generator 135 (e.g., to generate various internal clock signals) and/or to a command decoder 115.

The command/address terminals may be supplied with addresses signals ADDR from outside the memory device 100 (e.g., from a memory controller). The address signals ADDR supplied to the address terminals can be transferred, via the command/address input circuit 105, to an address decoder 110. The address decoder 110 can receive the address signals ADDR and supply a decoded row address signal (XADD) to the row decoder 140, and a decoded column address signal (YADD) to the column decoder 145. The address decoder 110 can also supply a decoded bank address signal (BADD) to the row decoder 140 and to the column decoder 145. The decoded bank address signal (BADD) can specify a memory bank 152 of the memory array 150 containing the decoded row address XADD and the decoded column address YADD.

The command/address terminals may further be supplied with command signals CMD and/or chip select signals CS from outside the memory device 100. The command signals may represent various memory commands (e.g., refresh commands; activate commands; precharge commands; access commands, such as read commands and write commands; timing commands; etc.) from a memory controller. The access commands may be associated with one or more row addresses XADD, column addresses YADD, and bank addresses BADD to indicate which memory cells of the memory array 150 to access. The chip select signal CS may be used to select the memory device 100 to respond to commands and addresses provided to the command and address terminals of the memory device 100. When an active CS signal is provided to the memory device 100, the commands and addresses can be decoded and memory operations can be performed. When the CS signal is not active, the memory device 100 can ignore commands and/or addresses provided to the command and address terminals.

The command signals CMD received at the command terminals may be supplied to the command decoder 115, via the command/address input circuit 105, as internal command signals ICMD. The command decoder 115 can include circuits to decode the internal command signals ICMD and generate various internal signals and commands for performing memory operations. For example, the command decoder 115 can provide a row command signal to select a word line and a column command signal to select a bit line (e.g., in response to receiving an access command). Other examples of memory operations that the memory device 100 may perform based on decoding the internal command signals ICMD include refresh commands (e.g., re-establishing full charges stored in individual memory cells of the memory array 150), activate commands (e.g., activating a row in a particular memory bank 152, in some cases for subsequent access operations), or precharge commands (e.g., deactivating the activated row in the particular memory bank 152).

The command decoder 115, in some embodiments, may further include one or more registers 128 for tracking various counts and/or values (e.g., counts of refresh commands received by the memory device 100 or self-refresh operations performed by the memory device 100) and/or for storing various operating conditions for the memory device 100 to perform certain functions, features, and modes (or test modes). As such, in some embodiments, the registers 128 (or a subset of the registers 128) may be referred to as mode registers. Additionally, or alternatively, the memory device 100 may include registers 128 as a separate component outside of the command decoder 115. In some embodiments, the registers 128 may include multi-purpose registers (MPRs) configured to write and/or read specialized data to and/or from the memory device 100.

When a read command is issued to a memory bank 152 with an open row and a column address is timely supplied as part of the read command, read data can be read from memory cells in the memory array 150 designated by the row address (which may have been provided as part of the activate command identifying the open row) and the column address. The read command may be received by the command decoder 115, which can provide internal commands so that read data from the memory array 150 is output from the memory device 100 via the read/write amplifiers 155 and the input/output circuit 160, using the data terminals DQ, DBI, and/or DMI, and/or according to the DQS clock signal. The read data may be provided at a time defined by read latency information that can be programmed in the memory device 100, for example, in a mode register (e.g., one or more of the registers 128). The read latency information can be defined in terms of clock cycles of the CK clock signal. For example, the read latency information can be a number of clock cycles of the CK signal after the read command is received by the memory device 100 when the associated read data is provided.

When a write command is issued to a memory bank 152 with an open row and a column address is timely supplied as part of the write command, write data can be supplied to the data terminals DQ, DBI, and/or DMI. The write data can be supplied to the data terminals DQ, DMI, and/or DMI according to the WCK and WCKF clock signals. The write command may be received by the command decoder 115, which can provide internal commands to the input/output circuit 160 so that the write data can be received by data receivers in the input/output circuit 160, and supplied to the memory array 150 via the read/write amplifiers 155. The write data may be written in the memory cell designated by the row address and the column address. The write data may be provided to the data terminals at a time that is defined by write latency WL information. The write latency WL information can be programmed in the memory device 100, for example, in a mode register (e.g., one or more of the registers 128). The write latency WL information can be defined in terms of clock cycles of the CK clock signal. For example, the write latency information WL can be a number of clock cycles of the CK signal after the write command is received by the memory device 100 when the associated write data is received.

FIG. 2 is a diagram schematically illustrating a plurality of sub-word line drivers 210-217 (“SWDs 210-217”) configured in accordance with various embodiments of the present technology. As shown, each of the SWDs 210-217 is coupled to (a) a corresponding one of a plurality of word lines WL0-WL7 of a memory cell MAT 252, and (b) a corresponding one of a plurality of phase signal lines PH0-PH7. Each of the phase signal lines PH0-PH7 can be driven by a corresponding phase driver FXD (not shown).

In the illustrated embodiment, the word lines WL0-WL7 terminate at or proximate the memory cell MAT 252. Stated another way, the word lines WL0-WL7 do not pass through to the global memory array (e.g., the global memory array 150 of FIG. 1B). As discussed above, such a configuration of word lines is easier and less costly to fabricate or manufacture than a pass-through configuration of word lines. In other embodiments of the present technology, the word lines can pass through to the global memory array.

Each of the SWDs 210-217 in FIG. 2 is further coupled to one of two global word lines GR0 and GR1. More specifically, the SWDs 210, 212, 214, and 216 are each coupled to the global word line GR0, and the SWDs 211, 213, 215, and 217 are each coupled to the global word line GR1. The global word lines can be driven by a corresponding main word line driver MWD (not shown). The MWD that drives the global word line GR0 can be different from the MWD that drives the global word line GR1.

The word lines WL0, WL2, WL4, and WL6 (corresponding to the SWDs 210, 212, 214, and 216 and to the global word line GR0) are interleaved with the word lines WL1, WL3, WL5, and WL7 (corresponding to the SWDs 211, 213, 215, and 215 and to the global word line GR1) in the memory cell MAT 252. More specifically, word lines from a first set comprising the word lines WL0, WL2, WL4, and WL6 alternate with word lines from a second set comprising the word lines WL1, WL3, WL5, and WL7, such that the word lines WL0, WL2, WL4, and WL6 of the first set are positioned every other word line in the memory cell MAT 252. Stated another way, the word lines WL0, WL2, WL4, and WL6 of the first set are interleaved with the word lines WL1, WL3, WL5, and WL7 of the second set such that two of the word lines WL1, WL3, WL5, and WL7 of the second set (e.g., the word lines WL1 and WL3) (a) flank opposite sides of one of the word lines WL0, WL2, WL4, and WL6 of the first set (e.g., the word line WL2) and (b) are positioned immediately adjacent the one of the word lines WL0, WL2, WL4, and WL6 of the first set. In other words, the word lines WL0-WL7 of FIG. 2 are positioned in the memory cell MAT 252 such that each of the word lines WL0, WL2, WL4, and WL6 of the first set are positioned immediately adjacent at least one of the word lines WL1, WL3, WL5, and WL7 of the second set, and vice versa. As discussed in greater detail below with reference to FIGS. 3A and 3B, use of two global word lines and the interleaved positioning of the word lines WL0-WL7 can enable shielding of floating ones of the word lines WL0-WL7 while another one of the word lines WL0-WL7 is selected and fired.

The SWDs 210-217 of FIG. 2 each includes a single (e.g., only one) transistor 220-227. In some embodiments, each of the SWDs 210-217 only includes a single transistor. In other embodiments, each of the SWDs 210-217 includes a single transistor and may include other components (not shown) that are not transistors. In the illustrated embodiment, the transistors 220-227 are MOSFET transistors. More specifically, the transistors 220-227 are nMOS transistors. In other embodiments of the present technology, an SWD can include a single pMOS transistor, or a single instance of another type of transistor.

Referring to the sub-word line driver 214 as an example, the sub-word line driver 214 includes a single nMOS transistor 224. The nMOS transistor 224 includes a gate coupled to the phase signal line PH4 and configured to receive a phase voltage signal driven onto the phase signal line PH4 by a corresponding FXD (not shown). The nMOS transistor 224 further includes (a) a source coupled to word line WL4 and (b) a drain coupled to the global word line GR0. In embodiments in which the transistor 224 is a pMOS transistor, a source of the transistor 224 can be coupled to the global word line GR0, and a drain of the transistor 224 can be coupled to the word line WL4.

Use of a single transistor (e.g., to selectively couple a corresponding word line to a corresponding global word line) in each of the sub-word line drivers 210-217 can reduce the amount of space occupied or consumed by each of the sub-word line drivers 210-217 in comparison to a sub-word line driver that includes multiple transistors (e.g., to selectively couple a word line to a global word line). In some embodiments, the reduction of the footprints of the sub-word line driver 210-217 can contribute to realizing a smaller size (e.g., a smaller chip size) of the overall memory device (e.g., the memory device 100 of FIG. 1B). Additionally, or alternatively, use of a single transistor (e.g., to selectively couple a corresponding word line to a corresponding global word line) enables use of a single (e.g., only one) phase driver FXD to selectively activate the single transistor, as discussed in greater detail below. Thus, the present technology is expected to reduce the power consumption of a memory device in comparison to memory devices employing sub-word line drivers that each incorporate multiple transistors and that are each coupled to multiple phase drivers to selectively activate those transistors. In addition, because the present technology can utilize a single FXD per sub-word line driver, the size of the memory array 150 and/or the size of the overall memory device can be reduced in comparison to memory arrays and memory devices that employ multiple FXDs per sub-word line driver.

As discussed in greater detail below with reference to FIGS. 3A and 3B, the selection of a SWD from the SWDs 210-217, and thus a selection of a corresponding word line from the word lines WL0-WL7, is determined by the phase voltage signals driven onto the phase signals lines PH0-PH7 and the voltages driven onto the global word lines GR0 and GR1. Referring to the sub-word line driver 214 again as an example, a phase voltage signal driven onto the phase signal line PH4 can be used to switch (e.g., selectively activate or deactivate) the nMOS transistor 224. As a specific example, the FXD corresponding to the phase signal line PH4 can set a voltage on the phase signal line PH4 at a low state (e.g., Vnwl, V_{SS}, V_{OFF}, or another low voltage value), which can deactivate the nMOS transistor 224 and leave the corresponding word line WL4 floating. As another specific example, the FXD corresponding to the phase signal line PH4 can set a voltage on the phase signal line PH4 at a high state (e.g., V_{CC}, V_{CCP}, V_{CCP2}, or another high voltage value) or at an intermediate state (e.g., V_{DRV} or another intermediate voltage value), which can activate the nMOS transistor 224. When the nMOS transistor 224 is activated, the voltage on the word line WL4 follows (e.g., is pulled up to, is pulled down to, remains at) a voltage on the global word line GR0. In some embodiments, the FXD can set the voltage on the phase signal line PH4 to the high state when the word line WL4 is selected and fired for memory operations, and can set the voltage on the phase signal line PH4 to the intermediate state when the word line WL4 (or other word lines coupled to the global word line GR0) is used to shield floating words lines coupled to the global word line GR1. Shielding of floating word lines is discussed in greater detail below with reference to FIGS. 3A and 3B. The other sub-word line drivers 210-213 and 215-217 can be operated in a manner similar to and consistent with the discussion of the sub-word line driver 214 above.

In implementations in which the transistor 224 is a pMOS transistor, the phase voltage signal driven onto the phase signal line PH4 can be (a) set at the high state to deactivate the transistor 224 and leave the word line WL4 floating or (b) set at the low state (or the intermediate state) to activate the transistor 224 such that the voltage on the word line WL4 follows the voltage on the global word line GR0. The intermediate state for embodiments incorporating pMOS transistors can be at a lower voltage level than the intermediate state used in nMOS implementations of the present technology.

The voltages on the global word lines GR0 and GR1 can be set at a low state (e.g., Vnwl, V_{SS}, V_{OFF}, or another low voltage value) or at a high state (e.g., V_{CC}, V_{CCP}, V_{CCP2}, or another high voltage value). Thus, referring to the sub-word line driver 214, when the phase voltage signal on the phase signal line PH4 is set at the high state or at the intermediate state, the voltage on the word line WL4 can be set at a low state (e.g., Vnwl, V_{SS}, V_{OFF}, or another low voltage value) or at a high state (e.g., V_{CC}, V_{CCP}, V_{CCP2}, or another high voltage value), depending on the voltage on the global word line GR0. As discussed in greater detail below, the voltage on the word line WL4 can be set at the high state when the word line WL4 is selected and fired. When the word line WL4 is selected and fired (e.g., when the transistor 224 is activated and a voltage on the word line WL4 is set at the high state), memory cells (not shown) corresponding to the word line WL4 can be accessed for memory operations (e.g., read, write, erase, refresh, etc.) based at least in part on the voltage on the global word line GR0. Additionally, or alternatively, the voltage on the word line WL4 can be set at the low state, for example, when (a) an adjacent word line (e.g., either the word line WL3 or the word line WL5) is selected and fired, and (b) the word line WL4 is used to shield a floating word line (e.g., the other of the word line WL3 or the word line WL5 that is not selected and fired).

FIG. 3A is a signal diagram 380 illustrating a method of operating the sub-word line drivers 210-217 of FIG. 2 in accordance with various embodiments of the present technology. More specifically, the signal diagram 380 illustrates a method of operating the sub-word line drivers 210-217 to select and fire the word line WL4. For the sake of clarity, voltages on the word lines WL2, WL4, and WL6 are not shown in FIG. 3A but are discussed in detail below.

An initial state of the signals is shown at time t0 in FIG. 3A. In particular, the voltage on each of the phase signal lines PH0-PH7 is initially set at an intermediate state. For the sake of example, the intermediate state in FIG. 3A corresponds to a voltage V_{DRV}, or 1.8 volts. The voltage on each of the global word lines GR0 and GR1 is initially set at a low state. For the sake of example, the low state in FIG. 3A corresponds to a voltage Vnwl, or −0.15 volts.

Referring to FIGS. 2 and 3A together, setting the voltages on all of the phase signal lines PH0-PH7 to the intermediate state activates all of the transistors 220-227 corresponding to the sub-word line drivers 210-217. As such, the word lines WL0-WL7 are each coupled to a corresponding one of the global word lines GR0 and GR1 via a corresponding one of the transistors 220-227. In turn, the voltage on each of the word lines WL0-WL7 follows the voltage on the corresponding one of the global word lines GR0 and GR1. As discussed above, the voltage on each of the global word lines GR0 and GR1 is set at the low state. Thus, the voltage on each of the word lines WL0-WL7 is also initially set at the low state (e.g., voltage Vnwl, or −0.15 volts) at time t0. Although shown at a specific initial state at time t0 in FIG. 3A, the initial state of the voltage(s) on one or more of the phase signal lines PH0-PH7, one or more of the word lines WL0-WL7, the global word line GR0, and/or the global word line GR1 in other embodiments of the present technology can be different than shown in FIG. 3A or than discussed above.

At time t1 in FIG. 3A, word line WL4 is selected for memory operations. Thus, the voltage on the phase signal line PH4 is ramped to a high state to activate the transistor 224 of the sub-word line driver 214 corresponding to the word line WL4. For the sake of example, the high state for phase voltage signals in FIG. 3A corresponds to a voltage V_{CCP2} (or 4.2 volts).

At the same time, the transistors of all other sub-word line drivers that are coupled to a same global word line as the sub-word line driver that corresponds to the selected word line, are deactivated. As shown, the sub-word line drivers 210, 212, and 216 are each coupled to the same global word line (e.g., global word line GR0) as the sub-word line driver 214 that corresponds to the selected word line WL4. Therefore, in the illustrated example, the voltages on the phase signal lines PH0, PH2, and PH6 corresponding to sub-word line drivers 210, 212, and 216 are dropped to a low state to deactivate the transistors 220, 222, and 226. For the sake of example, the low state for phase voltage signals corresponds to the voltage Vnwl (or −0.15 volts).

Referring again to FIGS. 2 and 3A together, the high voltage on the signal line PH4 keeps the transistor 224 of the sub-word line driver 214 activated such that the word line WL4 continues to follow the voltage on the global word line GR0. The low voltages on the phase signal lines PH0, PH2, and PH6 deactivates the transistors 220, 222, and 226, respectively, of the sub-word line drivers 210, 212, and 216, respectively. Thus, the word lines WL0, WL2, and WL6 corresponding to the sub-word line drivers WL0, WL2, and WL6, respectively, are uncoupled from the global word line GR0 and are left floating. As shown in FIG. 3A, the voltages on the phase signal lines PH1, PH3, PH5, and PH7 and the voltage on the global word line GR1 (and therefore the voltages on the word lines WL1, WL3, WL5, and WL7) remain unchanged from time t0.

At time t2 in FIG. 3A, the voltage on the global word line (e.g., the global word line GR0) corresponding to the selected word line (e.g., the word line WL4) is ramped to a high state. For the sake of example, the high state for global word line voltage signals in FIG. 3A corresponds to a voltage V_{CCP}, or 3.1 volts. As discussed above, because the transistor 224 of the sub-word line driver 214 is activated via the high voltage on the phase signal line PH4 such that the word line WL4 is coupled to the global word line GR0 via the transistor 224, the voltage on the word line WL4 follows the voltage on the global word line GR0 from time t1 to time t4. Thus, as the voltage on the global word line GR0 is ramped to the high state at time t2 in FIG. 3A, the voltage on the word line WL4 is also ramped to the high state (e.g., voltage V_{CCP}, or 3.1 volts).

During time period between time t1 and time t4, the word lines WL0, WL2, and WL6 remain floating, so the voltages on those word lines do not change even as the voltage on the global word line GR0 is ramped at time t2. In addition, the voltages on the phase signal lines PH1, PH3, PH5, and PH7 and the voltage on the global word line GR1 remain unchanged. Thus, the voltages on the word lines WL1, WL3, WL5, and WL7 remain at the low state (e.g., Vnwl, or −0.15 volts).

FIG. 3B illustrates the embodiment shown in FIG. 2 in a state of operation corresponding to the time between time t2 and time t3 in FIG. 3A. As shown, the low voltages (e.g., Vnwl, or −0.15 volts) on the phase signal lines PH0, PH2, and PH6 have deactivated the transistors 220, 222, and 226, and have left the word lines WL0, WL2, and WL6 floating (as shown using dashed lines in FIG. 3B). In addition, the intermediate voltages (e.g., V_{DRV}, or 1.8 volts) on the phase signal lines PH1, PH3, PH5, and PH7 have activated the transistors 221, 223, 225, and 227, allowing the voltages on the word lines WL1, WL3, WL5, and WL7 to follow the voltage (e.g., Vnwl, or −0.15 volts) on the global word line GR1. Furthermore, the high voltage (e.g., V_{CCP2}, or 4.2 volts) on the phase signal line PH4 has activated the transistor 224 of the sub-word line driver 214, coupling the word line WL4 to the global word line GR0. Therefore, as the global word line GR0 is ramped to the high state (e.g., V_{CCP}, or 3.1 volts) at time t2, the voltage on the word line WL4 follows, and the word line WL4 is fired.

As shown in FIG. 3B, the word lines WL1, WL3, WL5, and WL7 (that are coupled to the global word line GR1) are interleaved with the word lines WL0, WL2, WL4, and WL6 (that are coupled to the global word line GR0). Thus, the word lines WL1, WL3, WL5, and WL7 are positioned immediately adjacent one of the floating word lines WL0, WL2, and WL6. In addition, each of the word lines WL1, WL3, WL5, and WL7 are positioned between (a) at least one of the floating word lines WL0, WL2, and WL6 and (b) the word line WL4. Such an arrangement allows the word lines WL1, WL3, WL5, and WL7 to shield immediately adjacent ones of the floating word lines WL0, WL2, and WL6 from coupling noise with the word line WL4 as the word line WL4 is fired (e.g., as the voltage on the word line WL4 is ramped to the high state, V_{CCP} or 3.1 volts). For example, as the word line WL4 is fired, the word line WL3 (being at the low state, Vnwl or −0.15 volts) can shield the floating word lines WL2 from the word line WL4. More specifically, the word line WL3 can shield the floating word line WL2 from coupling noise caused, for example, by parasitic capacitance 357.

Referring again to FIG. 3A, the voltage on the global word line GR0 is discharged or ramped down from the high state (e.g., V_{CCP}, or 3.1 volts) to the low state (e.g., Vnwl, or −0.15 volts) at time t3. In turn, the voltage on the word line WL4 follows and is therefore dropped to the low state by time t4.

At time t4, the voltages on the phase signals lines PH0, PH2, PH4, and PH6 are returned to the intermediate state (e.g., V_{DRV}, or 1.8 volts). More specifically, the voltage on the phase signal line PH4 is dropped from the high state (e.g., V_{CCP2}, or 4.2 volts) to the intermediate state, and the voltages on the phase signals lines PH0, PH4, and PH6 are ramped from the low state (Vnwl, or −0.15 volts) to the intermediate state. Thus, the transistors 220, 222, and 226 corresponding to the sub-word line drivers 210, 212, and 216, respectively, are activated as the voltages on the phase signal lines PH0, PH2, and PH6, respectively, are ramped to the intermediate state. Activation of the transistors 220, 222, and 226 couples the word lines WL0, WL2, and WL6, respectively, to the global word line GR0. Thus, the voltages on the word lines WL0, WL2, and WL6 are brought to the low state (e.g., Vnwl, or −0.15 volts).

Although the ramping of the various voltages is discussed and illustrated in a particular order in the signal diagram 380 of FIG. 3A, the present technology is not so limited. In other embodiments, the various voltages can be ramped or otherwise altered in a different order and/or at different times relative to each other. Furthermore, although shown at particular voltages levels in FIGS. 3A and 3B, different voltage levels can be used in other embodiments of the present technology.

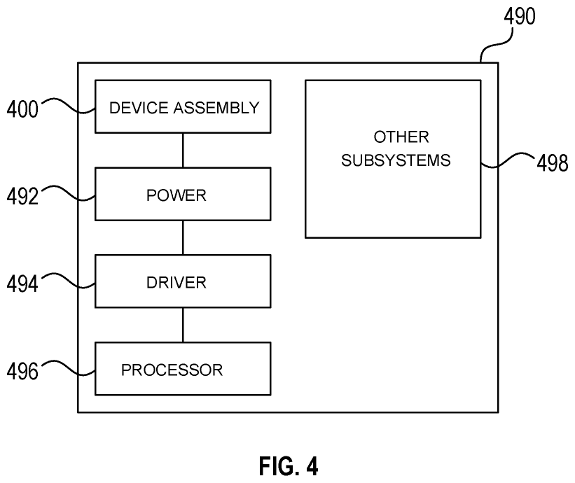

Any of the foregoing memory systems, devices, and/or methods described above with reference to FIGS. 1-3B can be incorporated into any of a myriad of larger and/or more complex systems, a representative example of which is system 490 shown schematically in FIG. 4. The system 490 can include a semiconductor device assembly 400, a power source 492, a driver 494, a processor 496, and/or other subsystems and components 498. The semiconductor device assembly 400 can include features generally similar to those of the memory systems, devices, and/or methods described above with reference to FIGS. 1-3B. The resulting system 490 can perform any of a wide variety of functions, such as memory storage, data processing, and/or other suitable functions. Accordingly, representative systems 490 can include, without limitation, hand-held devices (e.g., mobile phones, tablets, digital readers, and digital audio players), computers, vehicles, appliances, and other products. Components of the system 490 may be housed in a single unit or distributed over multiple, interconnected units (e.g., through a communications network). The components of the system 490 can also include remote devices and any of a wide variety of computer readable media.

As used herein, the terms “memory system” and “memory device” refer to systems and devices configured to temporarily and/or permanently store information related to various electronic devices. Accordingly, the term “memory device” can refer to a single memory die and/or to a memory package containing one or more memory dies. Similarly, the term “memory system” can refer to a system including one or more memory dies (e.g., a memory package) and/or to a system (e.g., a dual in-line memory module (DIMM)) including one or more memory packages.

Where the context permits, singular or plural terms can also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having” and “with” are used throughout to mean including at least the recited feature(s) such that any greater number of the same feature and/or additional types of other features are not precluded. Moreover, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; it will be understood by a person of ordinary skill in the art, however, that the signal may represent a bus of signals, where the bus may have a variety of bit widths.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology, as those skilled in the relevant art will recognize. For example, while steps are presented and/or discussed in a given order, alternative embodiments can perform steps in a different order. Furthermore, the various embodiments described herein can also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology. From the foregoing, it will also be appreciated that various modifications can be made without deviating from the technology. For example, various components of the technology can be further divided into subcomponents, or that various components and functions of the technology can be combined and/or integrated. Furthermore, although advantages associated with certain embodiments of the technology have been described in the context of those embodiments, other embodiments can also exhibit such advantages, and not all embodiments need necessarily exhibit such advantages to fall within the scope of the technology. Accordingly, the disclosure and associated technology can encompass other embodiments not expressly shown or described herein. To the extent any materials incorporated herein by reference conflict with the present disclosure, the present disclosure controls.

What is claimed is:

1. An apparatus, comprising:
a plurality of first sub-word line drivers, each coupled to (a) a first global word line and (b) a corresponding one of a plurality of first local word lines; and
a plurality of second sub-word line drivers, each coupled to (a) a second global word line different from the first global word line and (b) a corresponding one of a plurality of second local word lines,
wherein individual ones of the plurality of first local word lines are interleaved with individual ones of the plurality of second local word lines, and
wherein a sub-word line driver of the plurality of first sub-word line drivers includes a single transistor.

2. The apparatus of claim 1, wherein the single transistor includes a gate coupled to a phase driver.

3. The apparatus of claim 2, wherein the phase driver is the only phase driver configured to selectively control the sub-word line driver.

4. The apparatus of claim 1, wherein the single transistor includes an nMOS transistor.

5. The apparatus of claim 4, wherein the nMOS transistor includes (a) a drain coupled to the first global word line and (b) a source coupled to a local word line of the plurality of first local word lines.

6. The apparatus of claim 1, wherein the single transistor includes a pMOS transistor.

7. The apparatus of claim 1, wherein the first global word line is driven by a first main word line driver, and the second global word line is driven by a second main word line driver different from the first main word line driver.

8. The apparatus of claim 1, wherein the plurality of first local word lines and the plurality of second local word lines correspond to a memory cell matrix.

9. The apparatus of claim 8, wherein first local word lines of the plurality of first local word lines and second local word lines of the plurality of second local word lines terminate at the memory cell matrix and do not pass through to a global memory array.

10. The apparatus of claim 1, wherein the individual ones of the plurality of first local word lines are interleaved with individual ones of the plurality of second local word lines such that two second local word lines of the plurality of second local word lines (a) flank opposite sides of a first local word line of the plurality of first local word lines and (b) are each positioned immediately adjacent the first local word line.

11. The apparatus of claim 1, wherein the individual ones of the plurality of first local word lines are interleaved with individual ones of the plurality of second local word lines such that each first local word line of the plurality of first local word lines is positioned immediately adjacent at least one second local word line of the plurality of second word lines.

12. The apparatus of claim 1, wherein the apparatus is a memory array of a memory device, and wherein each of the first local word lines of the plurality of first local word lines and each of the local word lines of the plurality of second local word lines are coupled to memory cells at intersections with corresponding bit lines of the memory array.

13. The apparatus of claim 1, wherein the apparatus is a dynamic random-access memory (DRAM) device.

14. A method, comprising:
ramping, using a first sub-word line driver, a voltage on a first word line, wherein the first sub-word line driver is connected to a global word line, and wherein ramping the voltage on the first word line includes connecting the first word line to the first global word line via the first sub-word line driver; and
floating, while ramping the voltage on the first word line, a second word line using a second sub-word line driver connected to the global word line.

15. The method of claim 14, further comprising shielding, while ramping the voltage on the first word line and floating the second word line, the second word line from the first word line using a third word line positioned between the first word line and the second word line.

16. The method of claim 15, wherein:
the global word line is a first global word line; and
shielding the second word line from the first word line includes connecting, using a third sub-word line driver, the third word line to a second global word line different from the first global word line.

17. The method of claim 14, wherein connecting the first word line to the first global word line includes controlling a single transistor of the first sub-word line driver, and wherein controlling the single transistor includes activating the single transistor.

18. The method of claim 14, wherein floating the second word line include controlling a single transistor of the second sub-word line driver, and wherein controlling the single transistor includes deactivating the single transistor.

19. A method of operating a plurality of local word lines of a memory cell matrix, the method comprising:
firing a selected local word line of the plurality of local word lines, wherein the plurality of local word lines includes (a) a first set of local word lines that comprises the selected local word line and (b) a second set of local word lines, wherein each local word line of the first set is selectively coupled to a first main word line via a corresponding one of a plurality of first sub-word line drivers, wherein each local word line of the second set is selectively coupled to a second main word line different from the first main word line via a corresponding one of a plurality of second sub-word line drivers, wherein local word lines of the first set are interleaved with local word lines of the second set, and wherein a first sub-word line driver of the plurality of first sub-word line drivers corresponding to the selected local word line includes a single transistor; and
shielding, using local word lines of the second set, unselected local word lines of the first set while firing the selected local word line.

20. The method of claim 19, wherein firing the selected local word line includes activating the single transistor of the first sub-word line driver corresponding to the selected local word line such that (a) the selected local word line is coupled to the first main word line via the single transistor and (b) a voltage on the selected local word line follows a voltage on the first main word line.

21. The method of claim 20, wherein firing the selected local word line includes ramping the voltage on the first main word line while the selected local word line is coupled to the first main word line via the single transistor.

22. The method of claim 19, wherein firing the selected local word line includes deactivating transistors of first sub-word line drivers of the plurality of first sub-word line drivers that correspond to the unselected local word lines of the first set such that the unselected local word lines of the first set are floating.

23. The method of claim 22, wherein:
shielding the unselected local word lines of the first set includes coupling a local word line of the second set to the second main word line via a transistor of a sub-word line driver corresponding to the local word line of the second set such that a voltage on the local word line of the second set corresponds to a voltage on the second main word line; and
the local word line of the second set is positioned between the selected local word line and a floating one of the unselected local word lines of the first set.
